(19) United States
(12) Patent Application Publication
(10) Pub. No.: US 2011/0049513 A1
(43) Pub. Date: Mar. 3, 2011

(54) SEMICONDUCTOR DEVICE HAVING MULTILAYER WIRING STRUCTURE AND METHOD OF FABRICATING THE SAME

(75) Inventor: Hideatsu Yamanaka, Kanagawa-ken (JP)

(73) Assignee: KABUSHIKI KAISHA TOSHIBA, Tokyo (JP)

(21) Appl. No.: 12/868,097

(22) Filed: Aug. 25, 2010

(30) Foreign Application Priority Data
Aug. 25, 2009 (JP) P2009-194843

(51) Int. Cl. H01L 23/58; H01L 21/66

(52) U.S. Cl. 257/48; 438/17; 257/E21.521; 257/E23.001

(57) ABSTRACT

According to one embodiment, a semiconductor device having a multilayer wiring structure includes a function block and a test pad. The function block contains a DFT circuit. The test pad is formed in an intermediate wiring layer, and connected to the DFT circuit of the function block. A functional operation test of the function block is executed by using the test pad.

### CROSS REFERENCE TO RELATED APPLICATION

This application is based upon and claims the benefit of priority from the prior Japanese Patent Application No. 2009-194843, filed on Aug. 25, 2009, the entire contents of which are incorporated herein by reference.

### FIELD

Embodiments described herein relate generally to a semiconductor device having a multilayer wiring structure and method of fabricating the same.

### BACKGROUND

Recently, a technology of multilayer wiring process has been progressed greatly, a semiconductor device using seven or more wiring layers has been put in to practical use. Such a semiconductor device having a multilayer wiring structure often uses up to fifth layer as signal wiring layers, for instance. In order to improve the wiring density, the signal wirings are generally formed with minimum width in a wiring process, and a lot of signal wirings are employed. As a result, photo masks used in fabrication process are required high accuracy. Therefore, the ratio of a photo mask cost increases in an entire development cost.

The master slice system is one of the systems to reduce the photo mask cost of an individual product. In the semiconductor devices using the master slice system, several products are fabricated from common master wafers made beforehand. A necessary number of master wafers are distributed to each product. Specific wirings to each product are formed on the distributed master wafers. Final products are examined by each product test.

When the fraction of defective distributed master wafers is high, the fraction of defective final products is increased. When a lot of low yield wafers are used, shortage of shipment amount may occur.

To solve this problem, JP-A H9-167835 discloses a gate array LSI where wirings are connected between specific semiconductor elements to form a test circuit, after a master wafer making process. In the gate array LSI, a test is done at the stage where the semiconductor elements were formed. According to the test result, master wafers to be used for each product are decided. Therefore, distribution of the master wafers according to specification of each product is possible, and the yield of final products can be improved.

However, as a technical difficulty of forming the wiring layer has increased according to the recent progress of the multilayer wiring, the probability that the defect occurs in the wiring process has increased, too. Therefore, it is difficult to estimate the yield of final products even if a test is executed at the stage when semiconductor elements are formed, as is done in the above-mentioned gate array LSI.

Moreover, in recent years, master slice semiconductor devices having IP (Intellectual Property)s as common master parts have been provided. In each of the devices, clock wirings, power supply wirings, and internal signal wirings are formed preliminarily. In this type of master slice semiconductor devices, wafers, for which fabricating steps are finished until forming the intermediate wiring layers to be used for the signal wirings, are stocked as master wafers in a wafer bank. It is desired to be able to estimate the yield of final products with high accuracy when master wafers, which are wired so as to have such intermediate wiring layers, are used.

### BRIEF DESCRIPTION OF THE DRAWINGS

FIG. 1 is a schematic cross section of a semiconductor device at a stage formed up to an intermediate layer according to a first embodiment.

FIG. 2 shows an example of a connection between a test pad of the semiconductor device and an external test equipment according to the first embodiment.

FIG. 3 shows an example of a plural function blocks are placed in the semiconductor device according to the first embodiment.

FIG. 4 is a flow chart showing a fabrication process flow of the semiconductor device according to the first embodiment.

FIG. 5 is a schematic cross section of the semiconductor device at a stage formed up to a top layer according to the first embodiment.

FIG. 6 is a schematic plan view showing a configuration of a chip of a semiconductor device obtained at a stage of a master wafer according to a second embodiment.

FIG. 7A and FIG. 7B show examples of connecting between test pads and function blocks in the semiconductor device obtained at the stage of a master wafer according to the second embodiment.

FIG. 8 is a schematic plan view showing a chip of the semiconductor device obtained at a stage of a final product according to the second embodiment.

FIG. 9 is a flow chart showing a fabrication process flow of the semiconductor device according to the second embodiment.

FIG. 10 shows an example of distributing master wafers stocked in a wafer bank to individual products according to a method of fabrication of the second embodiment.

### DETAILED DESCRIPTION

According to one embodiment, a semiconductor device having a multilayer wiring structure includes a function block and a test pad. The function block contains a DFT circuit. The test pad is formed in an intermediate wiring layer, and connected to the DFT circuit of the function block. A functional operation test of the function block is executed by using the test pad.

Various further embodiments will be described with reference to the accompany drawings. The same reference numerals denote the same or similar parts throughout the drawings respectively.

### First Embodiment

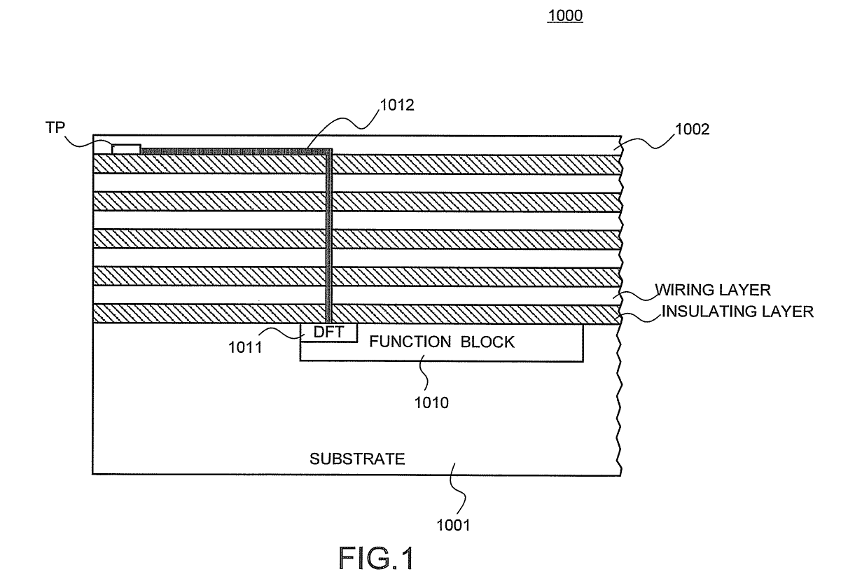

FIG. 1 shows a schematic cross section of a semiconductor device at a stage formed up to an intermediate layer according to a first embodiment. A semiconductor device of this embodiment has a multilayer wiring structure which an insulating layer and a wiring layer are alternately stacked on a substrate 1001. FIG. 1 shows a configuration of a semiconductor device 1000 at a stage formed up to an intermediate layer 1002 of the multilayer wiring structure. The semiconductor device 1000 includes a function block 1010 formed on a surface of the substrate 1001. The function block 1010 contains a DFT (Design For Test) circuit 1011 to test a functional operation of itself easily.

The semiconductor device 1000 includes a test pad TP formed in the intermediate layer 1002. The test pad TP is connected to the DFT circuit 1011 by an interconnection wiring 1012. A functional operation test of the function block 1010 is executed by using the test pad TP. At that time, the test pad TP is connected to an external test equipment.

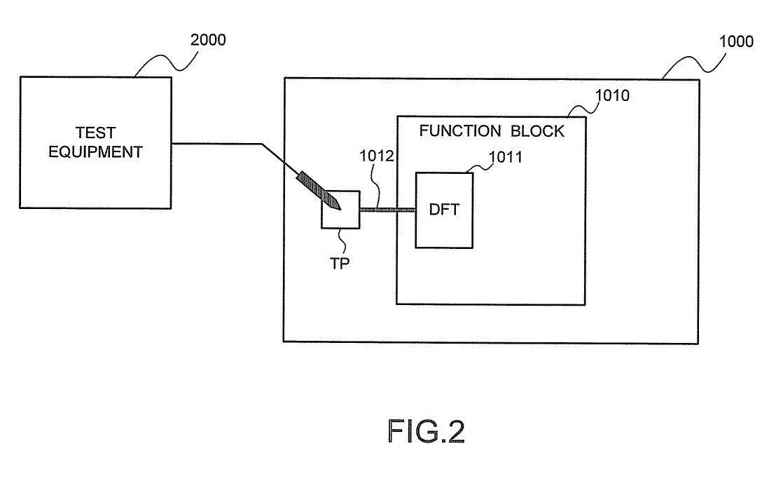

FIG. 2 shows an example of connection between test pad TP and an external test equipment 2000. The external test equipment 2000 operates the DFT circuit 1011, and tests the functional operation of the function block 1010.

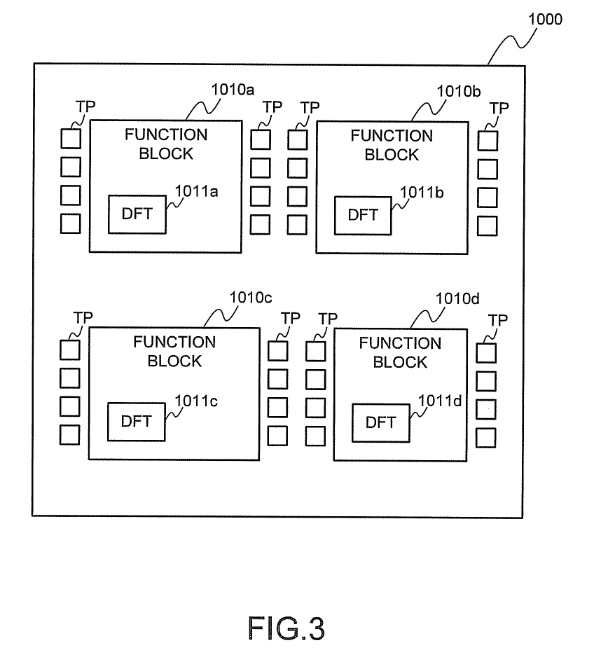

FIG. 3 shows an example of a plural function blocks are placed in the semiconductor device 1000. In this embodiment, function blocks 1010a, 1010b, 1010c and 1010d which have different function are included in the semiconductor device 1000. A plural test pads TP are arranged near each function block. These test pads TP are connected to DFT circuits 1011a, 1011b, 1011c and 1011d which are individually contained in each function block 1010a, 1010b, 1010c and 1010d.

Each functional operation test of the function blocks 1010a, 1010b, 1010c and 1010d is executed by connecting the test pads TP to the external test equipment and operating the DFT circuits 1011a, 1011b, 1011c and 1011d. A yield of each function block is calculated based on a result of above mentioned functional operation test.

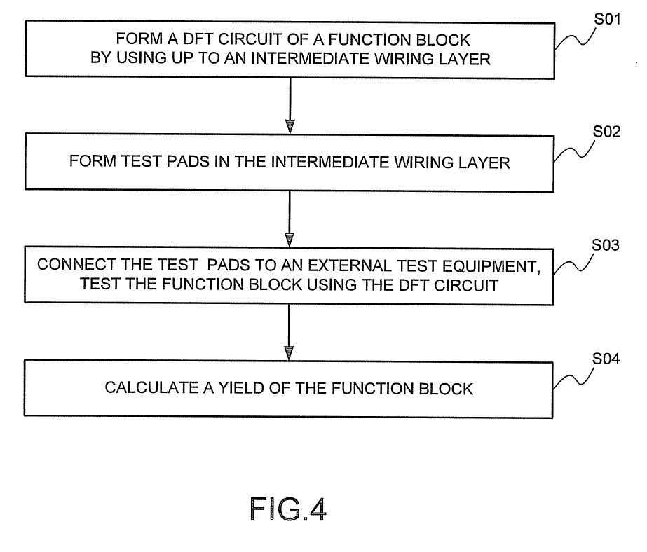

FIG. 4 shows a flow until calculating a yield of a function block in a fabricating process of the semiconductor device of this embodiment. In a fabrication of the semiconductor device of this embodiment, a DFT circuit of a functional block is formed by using up to an intermediate wiring layer (step S01), and test pads TP are formed in the intermediate wiring layer (step S02).

Next, by connecting test pads TP to an external test equipment, the function block is tested using the DFT circuit (step S03). And, a yield of the function block is calculated (step S04).

After the test of the functional block ends, one or more wiring layers above the intermediate wiring layer are formed above the middle wiring layer. And bonding pads BP are formed in a top wiring layer. The test pads TP formed in the intermediate wiring layer are connected to the bonding pads BP one by one.

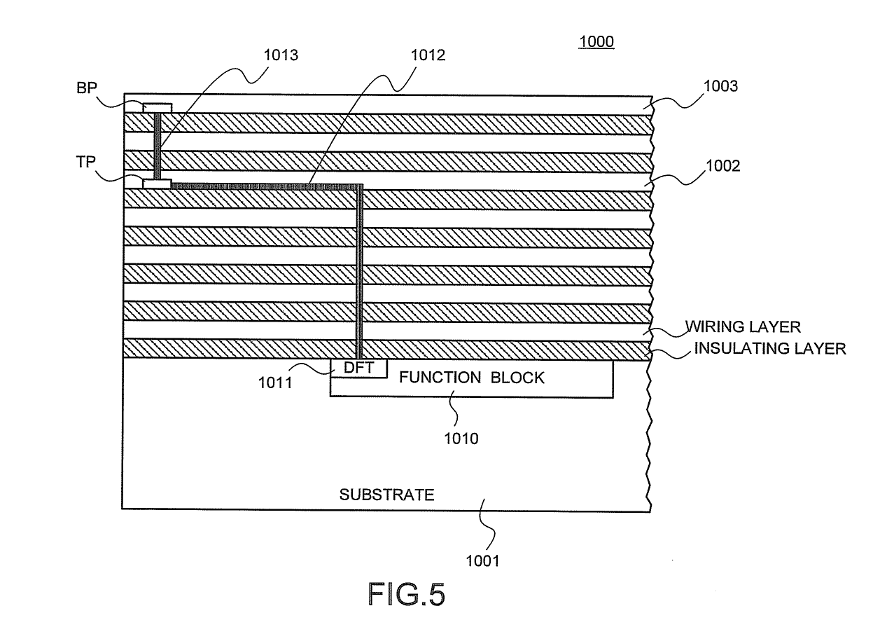

FIG. 5 shows a schematic cross section of a semiconductor device 1000 at a stage formed up to the top wiring layer 1003. The bonding pad BP is formed in the top wiring layer 1003. The test pad TP is connected to the bonding pad BP by an interconnection wiring 1013.

According to this embodiment, because the DFT circuit of the functional block is connected to the test pads of the intermediate wiring layer, the functional block can be tested by using the DFT circuit at the stage where the intermediate wiring layer has been fabricated. Also, a yield of the functional block can be calculated based on a result of the test

### Second Embodiment

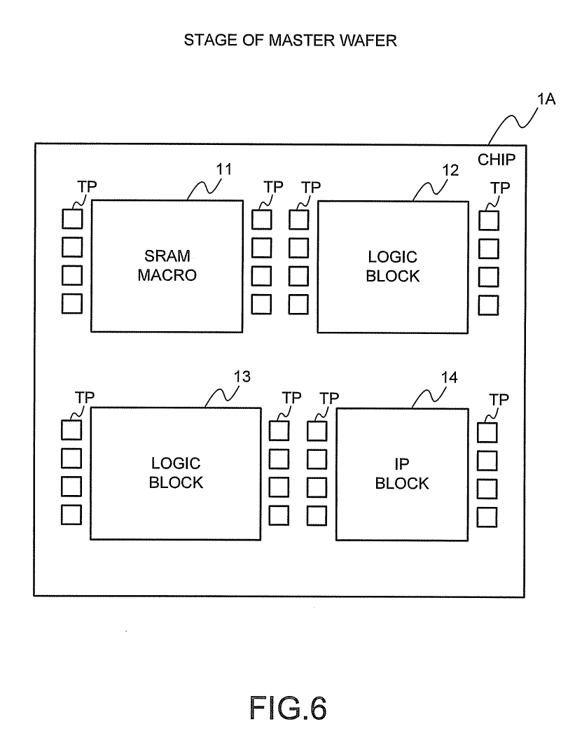

FIG. 6 shows a configuration of a chip of a semiconductor device obtained at a stage of a master wafer according to a second embodiment. This embodiment is a master slice semiconductor device having a multilayer wiring structure of seven layers, for instance. After ending the wiring process of the intermediate wiring layer (for instance, a fifth layer), wafers are stocked as master wafers in a wafer bank. In this embodiment, the universal function blocks are designed to operate usual function even at the stage of the master wafer. That is, the universal function blocks have power supply wirings, clock wirings, and internal signal wirings formed by using the wiring layers up to the fifth layer. Moreover, each function block has DFT circuits to be tested easily. These DFT circuits also have wirings necessary for the test execution which are formed by using the wiring layers up to the fifth layer.

Then, in this embodiment, test pads that use the fifth wiring layer are formed, and the test pads are connected to the DFT circuits included in each function block. Therefore, in this embodiment, the unit test for each function block at the stage of the master wafer can be executed by using the test pads and the DFT circuits.

For instance, in the chip 1A obtained at the stage of the master wafer shown in FIG. 6, plural test pads TP are arranged in the circumference of a SRAM macro 11, a logic block 12, a logic block 13, and an IP block 14 which are the function blocks used for various products commonly. Each test pad TP is connected to the DFT circuit included in each function block.

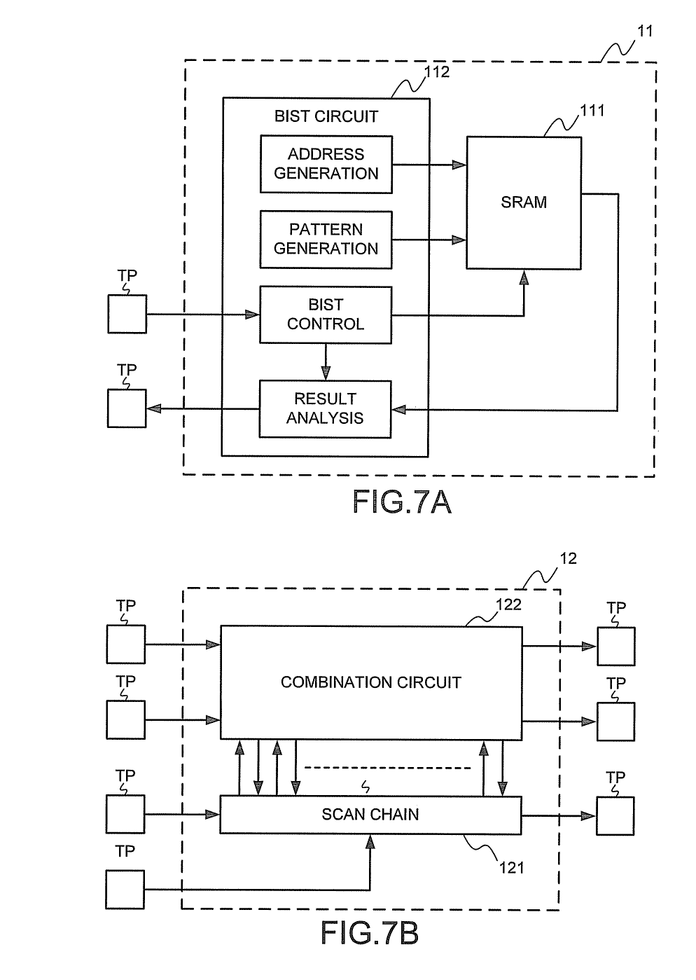

FIG. 7A and FIG. 7B show examples of connections of the DFT circuit included in the functional block and test pads TP.

FIG. 7A shows an example of connections between test pads TP and the DFT circuit in the SRAM macro 11. The SRAM macro 11 has a memory block SRAM111 and a BIST (Built-In Self Test) circuit 112 as a DFT circuit that tests the SRAM111. The BIST circuit 112 automatically generates addresses and test patterns which input to the SRAM111, and tests the SRAM111. In the example shown in FIG. 7A, test pads TP formed by using the fifth wiring layer are connected to input terminals and output terminals of the BIST circuit 112.

FIG. 7B shows an example of connections between test pads TP and the DFT circuit in the logic block 12. The logic block 12 has a scan chain 121 composed by scan flip-flops as a DFT circuit. A scan test of a combination circuit 122 can be executed by inputting a scan pattern to the scan chain 121. In the example shown in FIG. 2B, test pads TP formed by using the fifth wiring layer are connected to each input terminals and each output terminals of the scan chain 121 and the combination circuit 122.

As mentioned above, in this embodiment, the DFT circuit included in each function block is connected to test pads TP formed by the fifth wiring layer. Therefore, by connecting these test pads TP to external test equipment, the external test equipment can test each function block at the stage of the master wafer. As a result, the external test equipment can judge whether each chip is good or bad at the stage of the master wafer. After the test ends, the master wafer is stocked in the wafer bank once.

When an order of each product is received, post processes' of each product are executed for the master wafer respectively, and final products are completed. Test pads TP of the fifth wiring layer are covered with the structure of the upper layers by executing the post processes. Through these processes, bonding pads BP are formed by the top wiring layer (the seventh layer in this embodiment) instead of the test pads TP.

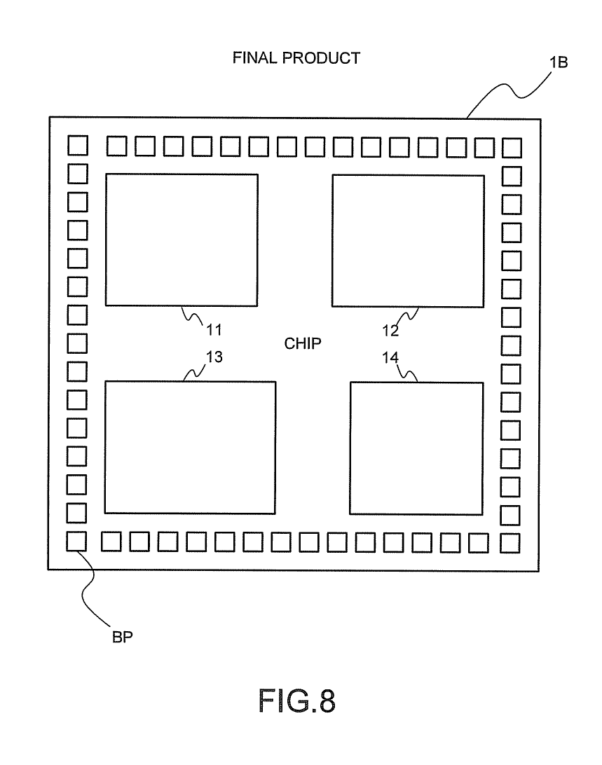

FIG. 8 shows the composition of a chip 1B of a final product. Bonding pads BP are arranged in the peripheral area of the chip. Finally, the DFT circuits included in each function block are connected to these bonding pads BP. By connecting these bonding pads BP to external test equipment, the external test equipment can test each function block by using the internal DFT circuits in the final products.

A following description explains a method of fabrication of an individual product by using the master wafer stocked in the wafer bank.

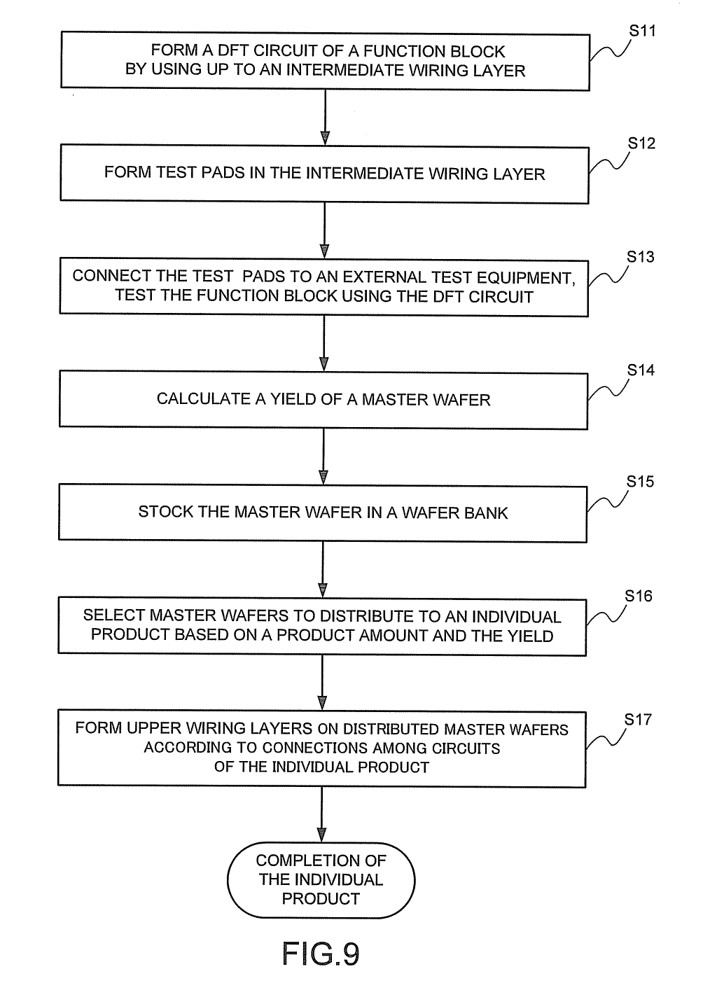

FIG. 9 is a flow chart of a fabricating process of an individual product that uses the master wafers of this embodiment. As a stage until fabricating master wafers, DFT circuits of each functional block are formed by using a fifth wiring layer that is an intermediate wiring layer (step S11), and test pads TP are formed in the fifth wiring layer (step S12).

Next, by connecting test pads TP to an external test equipment, each function block is tested using the DFT circuits (step S13), and a yield of each master wafer is calculated (step S14). At this point, fabrication of the master wafers finishes, and the master wafers are stocked in a wafer bank (step S15).

Afterwards, when an individual product is ordered, the master wafer which has an appropriate yield is selected from the wafer bank based on a product amount of the individual product (step S16). The appropriate yield is decided by considering various requirements like a product amount, delivery date or a cost. For example, where A is a product amount, C is a number of chips of a master wafer and Y is a yield of a master wafer, the master wafer which satisfies Y≧A/C is selected. When time for delivery is short, it becomes possible by sorting out high yield master wafers to secure the necessary quantity of good quality products. Furthermore, the master wafer with a comparatively low yield can be distributed to a product with a high cost advantage.

Finally, upper wiring layers (the 6th and the 7th layer) are formed to the selected master wafers (step S17), and the individual product is completed. Here, because design rules of the upper wiring layers concerning wiring width and pitch are wider than the lower wiring layers, there is no minute wiring in the upper wiring layers. Therefore, the fabrication of the upper wiring layers will hardly cause the decrease in the yield, and necessary amount of product is supplied enough.

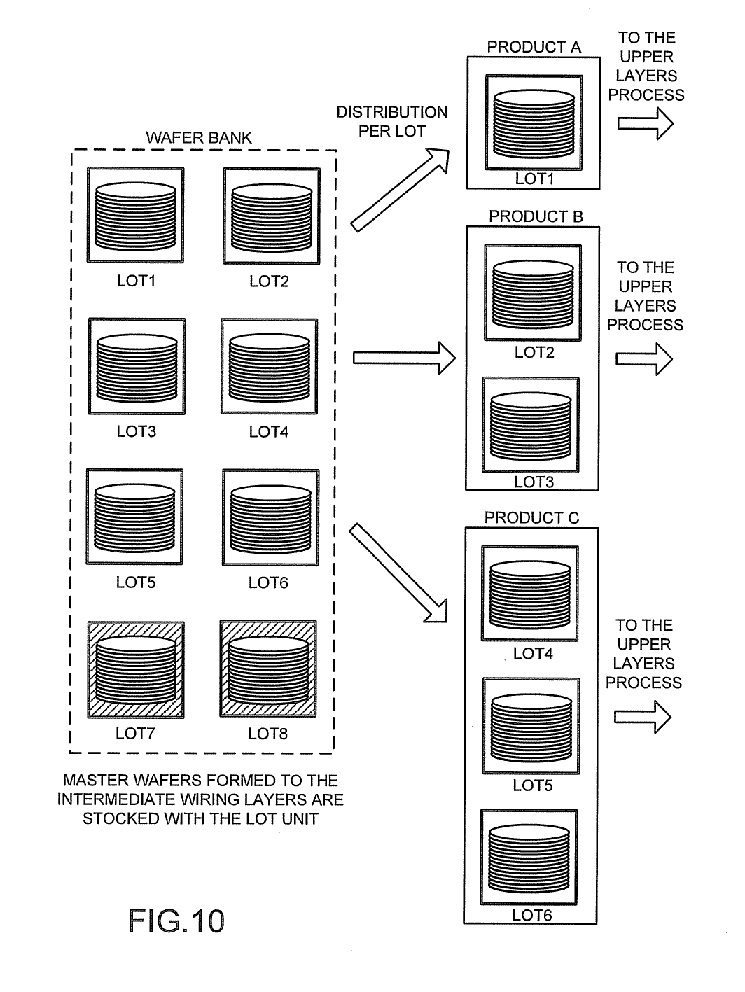

Next, a description concerning FIG. 10 explains a method of distributing the master wafers stocked in the wafer bank to several products. In an example shown in FIG. 10, the master wafers, which are fabricated to the intermediate wiring layers, are stocked in the wafer bank with the lot unit, and the yield of the master wafers is managed with the lot unit.

Then, the yield of each lot and the order amount of each product decides the number of lots distributed to each product. For instance, in the example shown in FIG. 10, one lot (LOT1) is distributed to product A, two lots (LOT2, LOT3) are distributed to product B, and three lots (LOT4, LOT5, LOT6) are distributed to product C. Afterwards, each product advances to the upper layers fabrication process, and completes final form.

As mentioned above, because the yield of master wafers is managed, a yield of each product keeps an expected value even at a final stage. In a conventional way, because the yield of master wafers is unknown, a low yield may cause a shortage of amount. However, in this embodiment, such a situation can be prevented being generated.

According to this embodiment, because the DFT circuits of each functional block, which are formed by using the lower and intermediate wiring layers, are connected to the test pads of the intermediate wiring layer, each functional block can be tested at the stage of the master wafer using the DFT circuits. As a result, the yield of each master wafer can be calculated, and the yield of final products can be estimated accurately. Therefore, in the products fabricated from these master wafers, a problem like a shortage of amount caused by a low yield can be prevented.

While certain embodiments have been described, these embodiments have been presented by way of example only, and are not indeed to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are indeed to cover such forms or modifications as would fall within the scope and spirit of the inventions.

What is claimed is:

1. A semiconductor device having a multilayer wiring structure comprising:
a function block containing a DFT circuit; and
a test pad being formed in an intermediate wiring layer and connected to the DFT circuit,
wherein a functional operation test of the function block is executed by using the test pad.

2. The semiconductor device according to claim 1, comprising:
one or more wiring layers being formed above the intermediate wiring layer; and
a bonding pad being formed in a top wiring layer of the wiring layers,
wherein the test pad being connected with the bonding pad.

3. A method of fabricating a semiconductor device having a multilayer wiring structure comprising:
forming a function block containing a DFT circuit;
forming an intermediate wiring layer above the function block;
forming a test pad being connected to the DFT circuit in the intermediate wiring layer,
wherein connecting the test pad to an external test equipment, and executing a functional operation test for the function block by using the test pad.

4. The method of fabricating according to claim 3, wherein the semiconductor device including a plural function blocks which having a different function respectively, the functional operation test being executed in each function block.

5. The method of fabricating according to claim 3, further comprising:
calculating a yield of the function block based on a result of the functional operation test.

6. The method of fabricating according to claim 3, further comprising:
forming one or more wiring layers above the intermediate wiring layer,
wherein the test pad being connected with the bonding pad being formed in a top wiring layer.

7. A method of fabricating a semiconductor device having a multilayer wiring structure employing a master slice system using a master wafer comprising:
forming a function block in the master wafer;
forming an intermediate wiring layer above the function block;
forming a test pad being connected to the function block in the intermediate wiring layer;
executing a test for the function block with connecting the test pad to an external test equipment; and
calculating a yield of the master wafer based on a result of the test.

8. The method of fabricating according to claim 7, wherein the function block containing a DFT circuit, the test pad being connected to the DFT circuit, the test for the function block is executed by using the test pad.

9. The method of fabricating according to claim 7, further comprising:
stocking the master wafer being calculated the yield in a wafer bank; and
selecting the master wafer having an appropriate yield for a product amount from among the wafer bank.

10. The method of fabricating according to claim 9, further comprising:
forming an upper wiring layer on the selected master wafer according to a circuit connection of an individual product.

11. The method of fabricating according to claim 9, wherein in stocking the master wafer in the wafer bank, the master wafer is stocked with a lot unit after the test finished.

12. The method of fabricating according to claim 10, wherein in forming the upper wiring layer according to the circuit connection of the individual product, forming a bonding pad being connected to the DFT circuit.

13. The method of fabricating according to claim 12, further comprising:
executing a test for the individual product by using the bonding pad and the DFT circuit.
